(19) United States
(12) Patent Application Publication
(10) Pub. No.: US 2015/0145041 A1
(43) Pub. Date: May 28, 2015

(54) SUBSTRATE LOCAL INTERCONNECT INTEGRATION WITH FINFETS

(71) Applicant: International Business Machines Corporation, Armonk, NY (US)

(72) Inventors: Ramachandra Divakaruni, Ossining, NY (US); Lars Wolfgang Liebmann, Poughquag, NY (US); Shom Ponoth, Gaithersburg, MD (US); Balasubramanian Pranatharthiharan, Watervliet, NY (US); Scott R. Stiffler, Sharon, CT (US)

(73) Assignee: International Business Machines Corporation, Armonk, NY (US)

(21) Appl. No.: 14/087,867

(22) Filed: Nov. 22, 2013

(51) Int. Cl. H01L 23/50; H01L 21/768; H01L 21/84; H01L 27/12

(52) U.S. Cl. CPC H01L 23/50; H01L 27/1211; H01L 21/76877; H01L 21/845
USPC 257/347; 257/368; 438/197

(57) ABSTRACT

A substrate local interconnect structure and method is disclosed. A buried conductor is formed in the insulator region or on the semiconductor substrate. The buried conductor may be formed by metal deposition, doped silicon regions, or silciding a region of the substrate. Metal sidewall portions connect transistor contacts to the buried conductor to form interconnections without the use of middle-of-line (MOL) metallization and via layers.

### FIELD OF THE INVENTION

The present invention relates generally to semiconductor fabrication, and more particularly, to substrate local interconnect integration with finFET devices.

### BACKGROUND OF THE INVENTION

There is a continued demand for smaller integrated circuits, while the desired functionality of electronic devices continues to increase. Increased circuit density is important for achieving these goals. CMOS density scaling is significantly limited by wiring density. Traditionally, first and second metal layers are used to make electrical contact between certain regions of the wafer. This significantly limits density scaling since, with fin type field effect transistors (FinFETs), density limits are constrained by middle-of-line (MOL) wiring density, and not by active fin density. Specifically, the first and second metallization layers seriously limit the density of integrated circuits. It is therefore desirable to have improvements in semiconductor fabrication that facilitate increased circuit density.

### SUMMARY OF THE INVENTION

In a first aspect, embodiments of the present invention provide a semiconductor structure comprising: a bulk semiconductor substrate; a buried oxide (BOX) layer disposed on the bulk semiconductor substrate; a silicon-on-insulator (SOI) layer disposed on the buried oxide (BOX) layer; a first transistor formed on the SOI layer, comprising a first source, drain and gate, wherein at least one of the first source, drain, and gate has a first contact disposed thereon; a second transistor formed on the SOI layer, comprising a second source, drain and gate wherein at least one of the second source, drain, and gate has a second contact disposed thereon; a buried conductor disposed at a level below the first contact and second contact; a first metal sidewall conductor connecting the first contact to the buried conductor; a second metal sidewall conductor connecting the second contact to the buried conductor; and an insulator layer disposed above the buried conductor.

In a second aspect, embodiments of the present invention provide a semiconductor structure comprising: a semiconductor substrate; a first transistor formed on the semiconductor substrate, comprising a first source, drain and gate, wherein at least one of the first source, drain, and gate has a first contact disposed thereon; a second transistor formed on the semiconductor substrate, comprising a second source, drain and gate wherein at least one of the second source, drain, and gate has a second contact disposed thereon; a buried conductor disposed at a level below the first contact and second contact; a first metal sidewall conductor connecting the first contact to the buried conductor; a first spacer disposed adjacent to the first metal sidewall conductor; a second metal sidewall conductor connecting the second contact to the buried conductor; a second spacer disposed adjacent to the first metal sidewall conductor; and an insulator layer disposed above and below the buried conductor.

In a third aspect, embodiments of the present invention provide a method of forming a semiconductor structure, comprising: forming a first transistor formed on a semiconductor substrate, comprising a first source, drain and gate, wherein at least one of the first source, drain, and gate has a first contact disposed thereon; forming a second transistor formed on the semiconductor substrate, comprising a second source, drain and gate wherein at least one of the second source, drain, and gate has a second contact disposed thereon; forming a buried conductor disposed at a level below the first contact and second contact; forming an insulator region above the buried conductor; forming a first metal sidewall conductor connecting the first contact to the buried conductor; and forming a second metal sidewall conductor connecting the first contact to the buried conductor.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 shows a top down view of a semiconductor structure at a starting point for embodiments of the present invention.

FIG. 2 shows a side view of a semiconductor structure after a subsequent process step of opening the buried oxide layer.

FIG. 3 shows a side view of a semiconductor structure after a subsequent process step of depositing a buried conductor metal.

FIG. 4 shows a side view of a semiconductor structure in an alternative embodiment after a subsequent process step of forming a buried conductor by forming a doped silicon region.

FIG. 5 shows a side view of a semiconductor structure after a subsequent process step of forming a contact and depositing an insulator layer.

FIG. 6 shows a side view of a semiconductor structure after a subsequent process step of recessing a portion of the insulator layer.

FIG. 7 shows a side view of a semiconductor structure after a subsequent process step of forming a metal sidewall to connect a contact to the buried conductor.

FIG. 8 shows a top-down view of a semiconductor structure in accordance with embodiments of the present invention.

FIG. 9 shows a side view of an alternative embodiment for silicon-on-insulator technology.

FIG. 10 shows a side view of an alternative embodiment for bulk technology.

FIG. 11 is a flowchart indicating process steps for embodiments of the present invention.

### DETAILED DESCRIPTION

Embodiments of the present invention provide increased circuit density with finFETs by utilizing a substrate local interconnect process. A buried conductor is formed in the insulator region or on the semiconductor substrate. The buried conductor may be formed by metal deposition, doped silicon regions, or silciding a region of the substrate. Metal sidewall portions connect transistor contacts to the buried conductor to form interconnections without the use of middle-of-line (MOL) metallization and via layers.

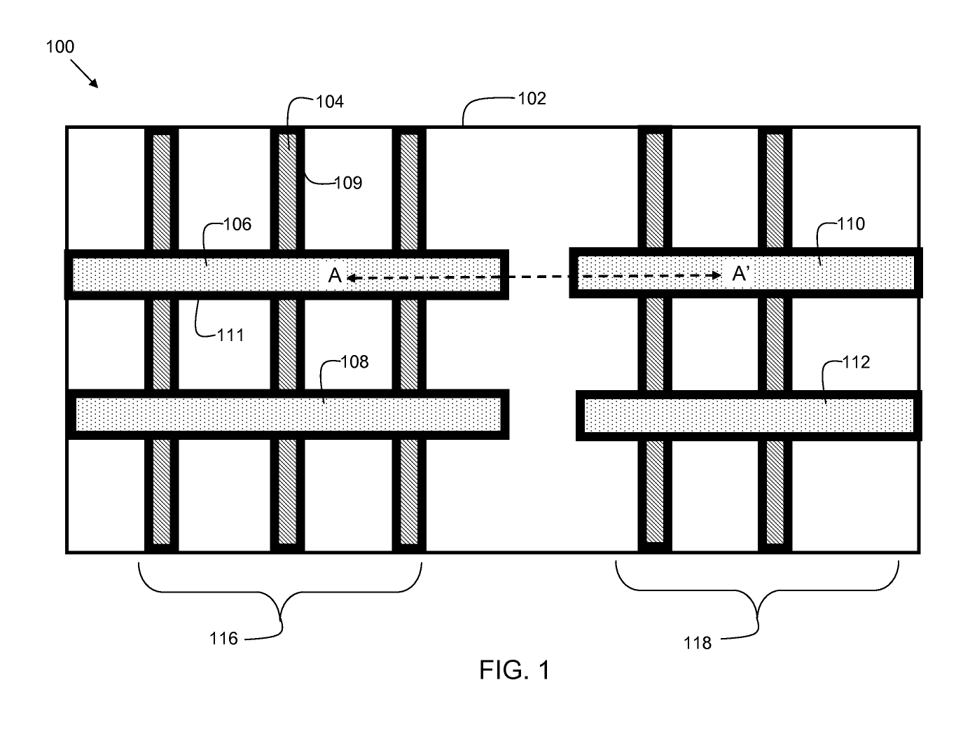

FIG. 1 shows a top down view of a semiconductor structure 100 at a starting point for embodiments of the present invention. A plurality of fins (indicated generally as 104) are formed on a semiconductor substrate 102. In embodiments, semiconductor substrate 102 may be a silicon substrate. Four gate strips (106, 108, 110, 112) are formed on the semiconductor substrate 102. Nitride spacers 109 are disposed adjacent to each fin 104. Similarly, nitride spacers 111 are formed adjacent to each gate strip. Gate strips 106 and 108 are part of transistor 116. Similarly, gate strips 110 and 112 are part of transistor 118. In many cases, it is desirable to connect the gate of one transistor to the gate of another transistor in order to implement a particular circuit design. Utilizing embodiments of the present invention, the gate of transistor 116 may be connected to the gate of transistor 118 without the use of MOL interconnections.

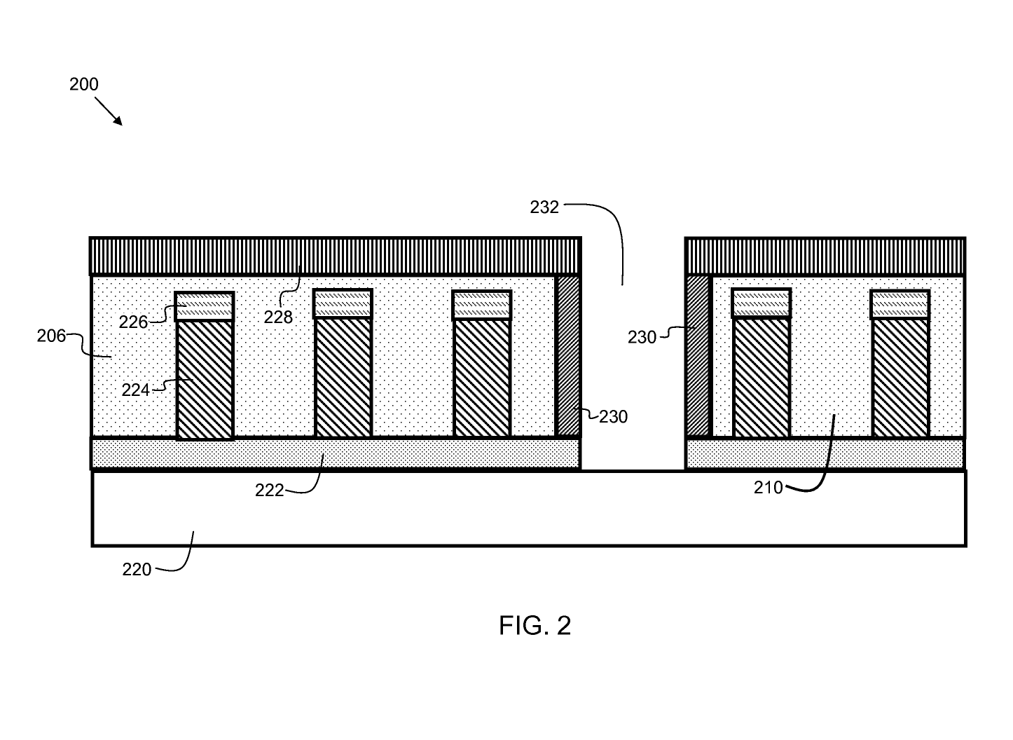

FIG. 2 shows a side view of a semiconductor structure 200 as viewed along line A-A′ of FIG. 1, after a subsequent process step of opening the buried oxide layer 222 by forming void 232. Void 232 may be formed using industry standard lithographic and etching techniques. As stated previously, similar elements may be referred to by similar numbers in various figures (FIGs) of the drawing, in which case typically the last two significant digits may be the same. For example, gate 206 of FIG. 2 is similar to gate 106 of FIG. 1. Fins, indicated generally as 224, are formed orthogonal to gate 206 and gate 210. A pad nitride layer 226 may be disposed on each fin. The fins 224 are disposed on a buried oxide (BOX) layer 222, which is disposed on silicon substrate 220. Nitride regions 230 are formed adjacent to the sides of gate 206 and gate 210. A hardmask layer 228 is formed on the top of gate 206 and gate 210. In some embodiments, the hardmask layer 228 may be comprised of oxide, such as silicon oxide.

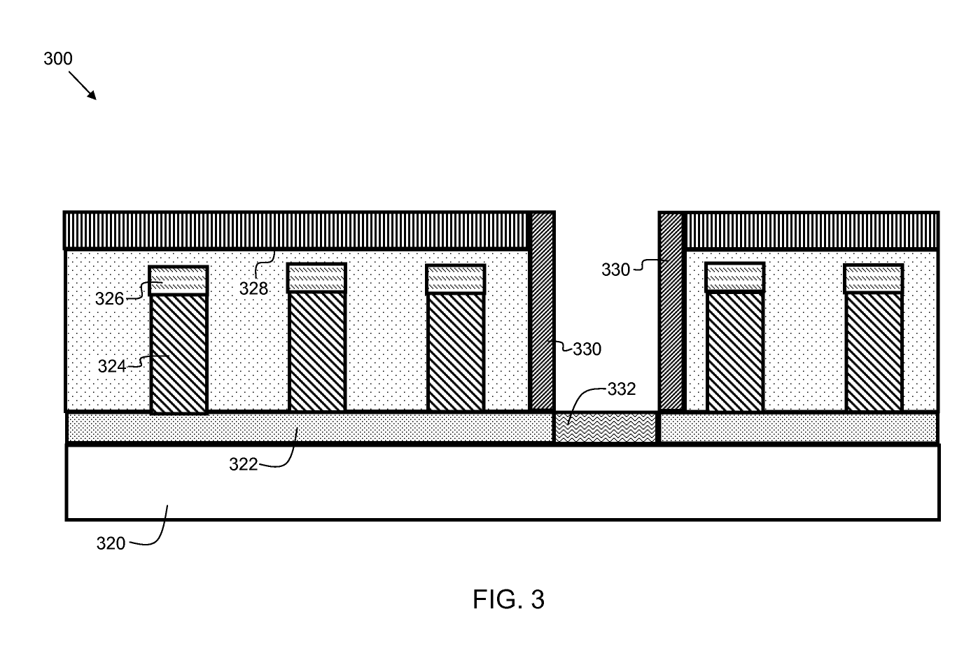

FIG. 3 shows a side view of a semiconductor structure 300 after a subsequent process step of forming a buried conductor 332. Buried conductor 332 may be formed by depositing a metal onto silicon substrate 320. The metal may include, but is not limited to, tungsten, copper, aluminum, and alloys thereof. The metal may be deposited by chemical vapor deposition (CVD), atomic layer deposition (ALD), or other suitable process.

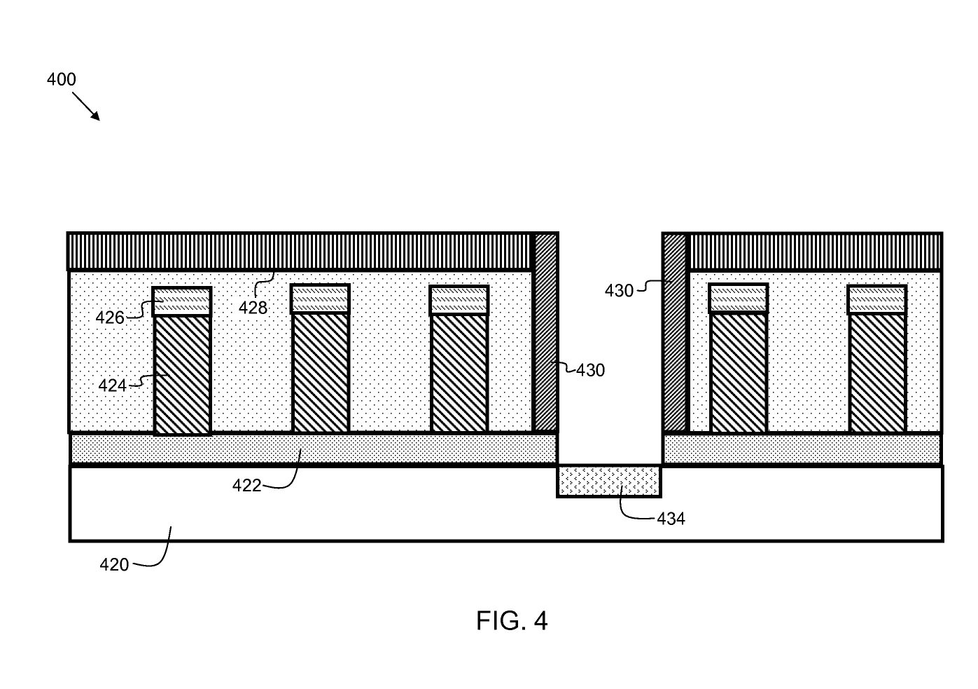

FIG. 4 shows a side view of a semiconductor structure 400 in an alternative embodiment after a subsequent process step of forming a buried conductor 434 by forming a doped silicon region on silicon substrate 420. In embodiments, the doped silicon region may be formed using arsenic, phosphorous, or boron dopants. Alternatively, buried conductor 434 may be formed using a silicide process. In some embodiments, the silicide may include, but is not limited to, nickel silicide, cobalt silicide, copper silicide, and aluminum silicide.

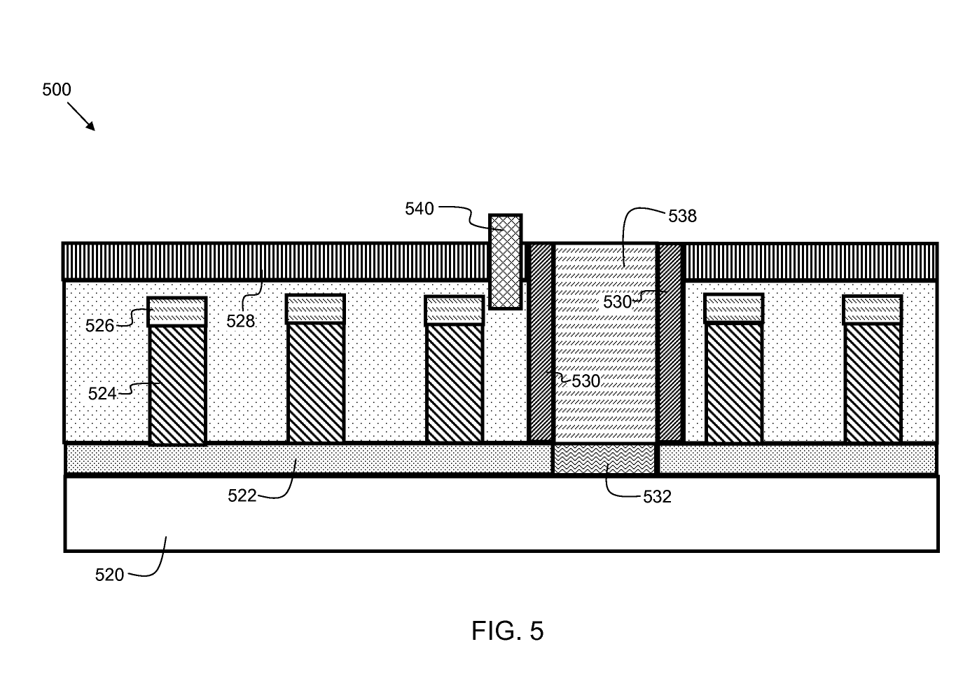

FIG. 5 shows a side view of a semiconductor structure 500 after a subsequent process step of forming a gate contact 540 and depositing an insulator layer 538. In embodiments, the insulator layer 538 may comprise an oxide, such as silicon oxide, and may be deposited by a chemical vapor deposition (CVD) process. The gate contact 540 may be comprised of tungsten or other suitable conductor.

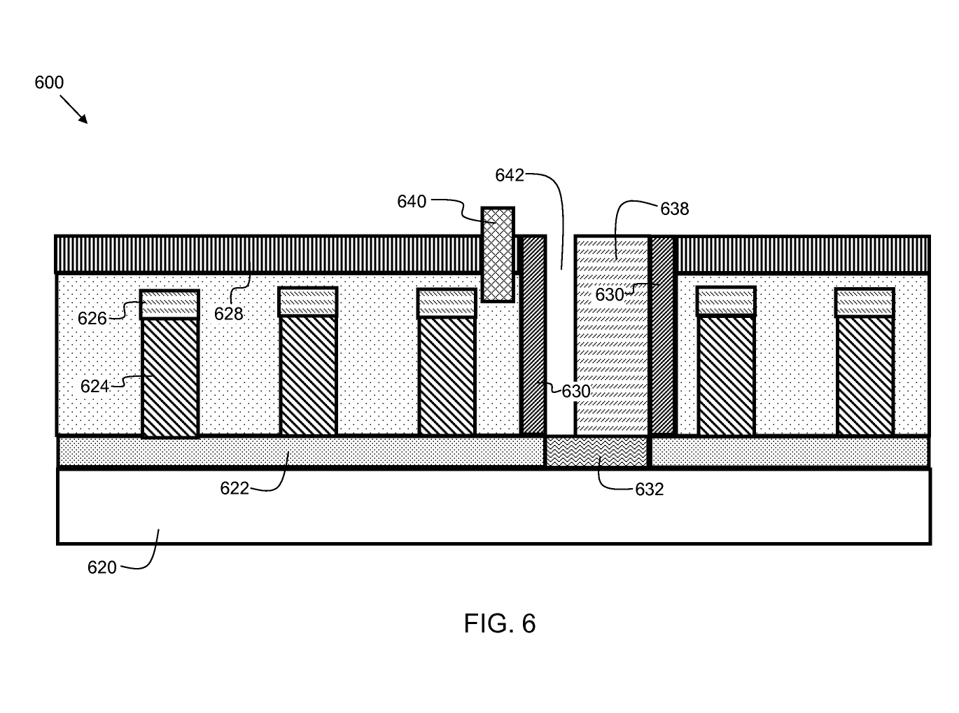

FIG. 6 shows a side view of a semiconductor structure 600 after a subsequent process step of recessing a portion of the insulator layer 638 to form cavity 642. Cavity 642 may be formed by a combination of lithographic process steps and anisotropic etch steps. In some embodiments, a reactive ion etch (RIE) process may be used in the forming of cavity 642.

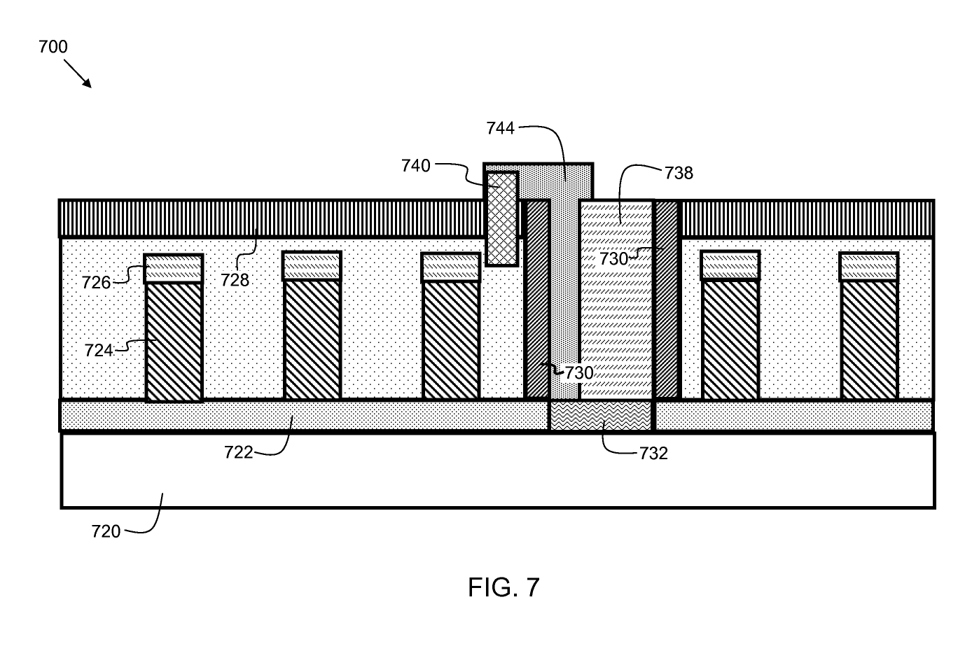

FIG. 7 shows a side view of a semiconductor structure 700 after a subsequent process step of forming a metal sidewall 744 to connect gate contact 740 to the buried conductor 732. The buried oxide layer 722 and nitride layer 730 provide electrical isolation between the fins 724 and the metal sidewall 744 and buried conductor 732.

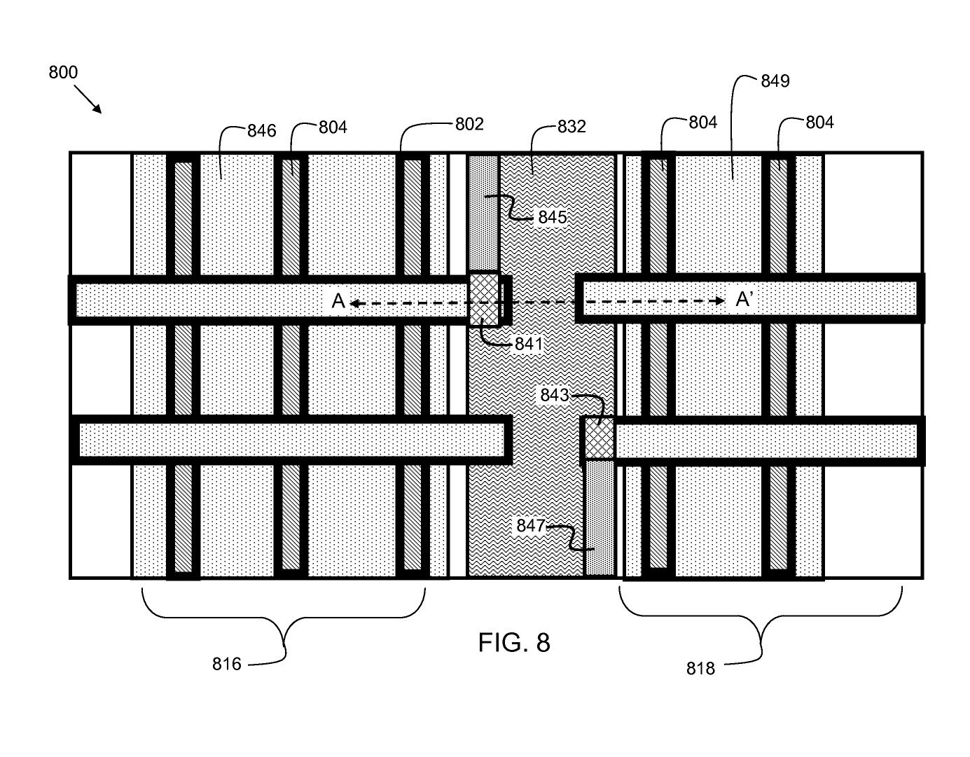

FIG. 8 shows a top-down view of a semiconductor structure 800 in accordance with embodiments of the present invention. Utilizing processes such as described for FIGS. 1-7, a buried conductor 832 is formed to connect the gate of transistor 816 to the gate of transistor 818. Line A-A′ of FIG. 8 represents a cross-section which is shown in FIG. 7. A gate contact 841 is formed on transistor 816. A gate contact 843 is formed on transistor 818. A metal sidewall region 845 connects contact 841 to buried conductor 832. A metal sidewall 847 connects contact 843 to buried conductor 832. Hence, transistors 816 and 818 have their gates connected to each other without the use of any wiring levels disposed above contacts 841 and 843. The buried conductor 832 is disposed at a level below the first contact 841 and second contact 843. Hence, the connection is not limited by the density of MOL wiring layers. Transistor 816 has its fins (shown generally as 804) merged by epitaxial region 846. Similarly, transistor 818 has its fins merged by epitaxial region 849. However, embodiments of the present invention may also be utilized with single-fin finFETs.

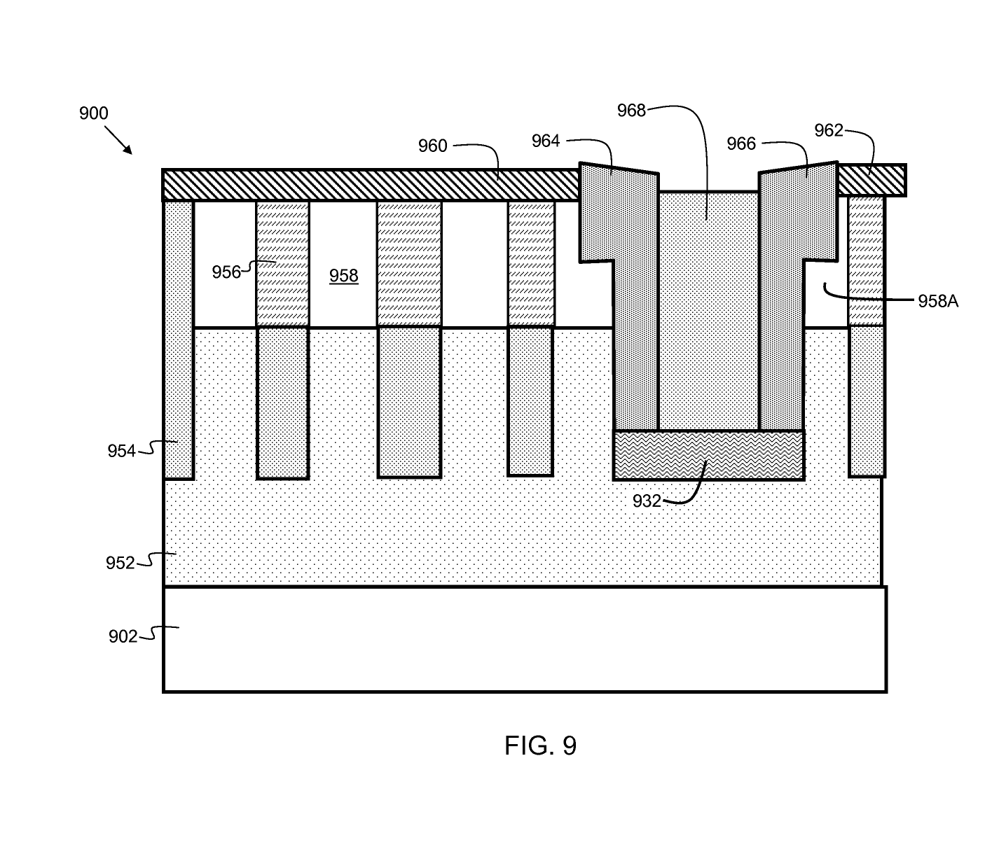

FIG. 9 shows a side view of an alternative embodiment 900 for silicon-on-insulator technology. A buried oxide (BOX) layer 952 is disposed on bulk semiconductor substrate 902. Substrate 902 may be a silicon substrate. A plurality of fins 958 are formed in a silicon-on-insulator (SOI) layer disposed above BOX layer 952. Local oxide 956 may be utilized to isolate the individual fins. In some embodiments, the local oxide 956 may be a flowable oxide. While the example of FIG. 8 showed the gates of two transistors connected together, in some cases it may be desirable to connect a source or drain of one finFET to a source or drain of another finFET. In the example of FIG. 9, a source/drain (S/D) contact 960 is formed on the fins of a first transistor. Similarly, S/D contact 962 contacts fin 958A of another transistor. Metal sidewall 964 connects contact 960 to buried conductor 932, which is disposed within the buried oxide (BOX) layer 952. Similarly, metal sidewall 966 connects contact 962 to buried conductor 932.

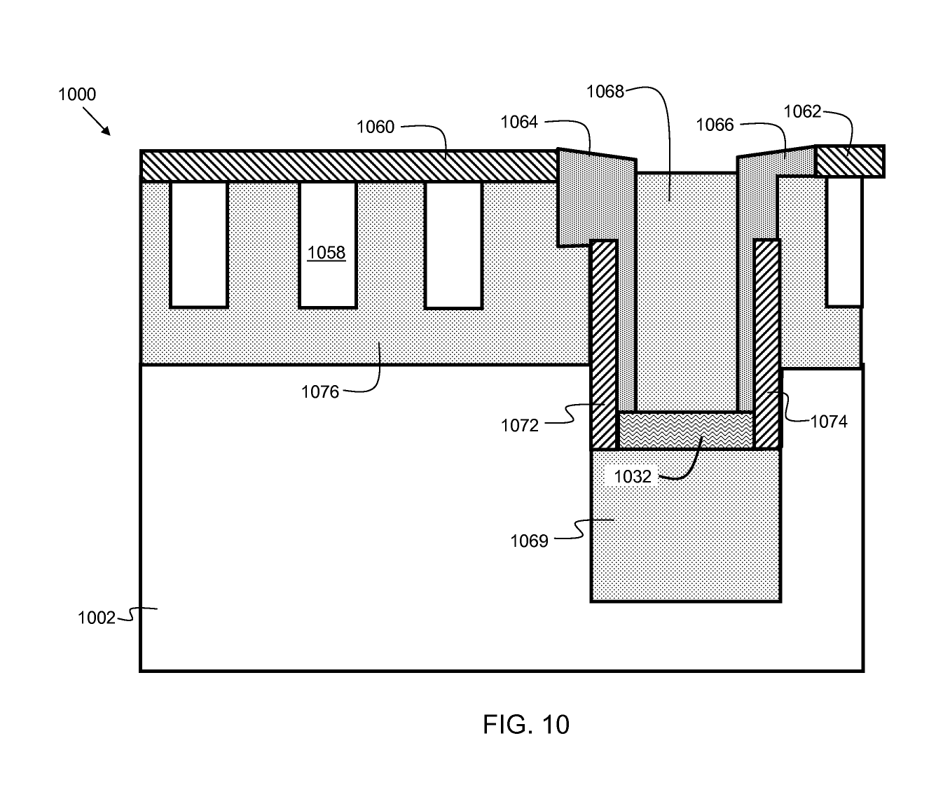

FIG. 10 shows a side view of an alternative embodiment 1000 for bulk technology. In this embodiment, the trench isolation is formed deeper, such that it extends into the bulk substrate 1002. A lower isolation portion 1069 is filled with an insulator, such as silicon oxide. Spacers 1072 and 1074 are formed on the sidewalls of the cavity. In the bulk embodiments, the spacers 1072 and 1074 provide isolation between the buried conductor 1032 and the rest of the substrate 1002, to prevent leakage. The buried conductor 1032 is then formed (e.g. using a metal deposition, such as tungsten). The upper portion 1068 of the insulator is then deposited, and then the metal sidewalls 1064 and 1066 are formed to connect contacts 1060 and 1062 with the buried conductor 1032.

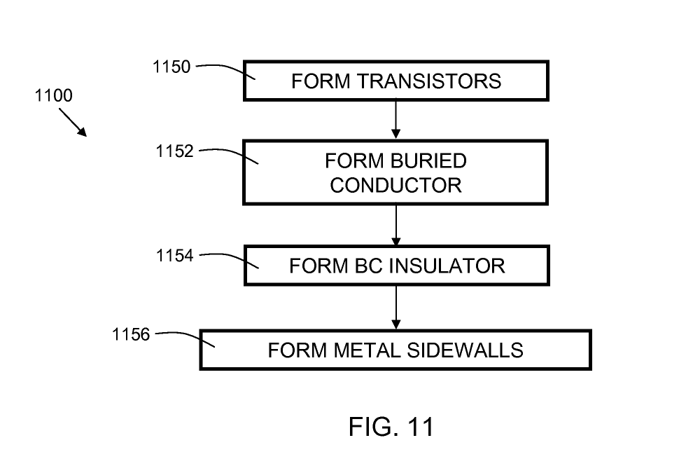

FIG. 11 is a flowchart indicating process steps for embodiments of the present invention. In process step 1150, transistors are formed. In process step 1152, a buried conductor is formed between two transistors that are to be connected. The two transistors may be adjacent to each other. In other embodiments, the two transistors may not be adjacent to each other, but may still be close enough together such that interconnection with MOL wiring is not efficient. The buried conductor may be formed in a variety of ways, including metal deposition, forming a silicided region of a silicon substrate, or doping a region of the silicon substrate. In some embodiments, the buried conductor may be formed such that it is not in contact with the bulk substrate, such as with 1032 in FIG. 10. In process step 1154, the buried conductor (BC) insulator is formed, such as 968 of FIG. 9. The buried conductor insulator may be comprised of an oxide, such as silicon oxide. In process step 1156, the metal sidewalls are formed that connect the desired contacts to the buried conductor. In embodiments, the metal sidewalls are comprised of tungsten. In other embodiments, another metal may be used, including, but not limited to, copper, aluminum, or gold.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A semiconductor structure comprising:
a bulk semiconductor substrate;
a buried oxide (BOX) layer disposed on the bulk semiconductor substrate;
a silicon-on-insulator (SOI) layer disposed on the buried oxide (BOX) layer;
a first transistor formed on the SOI layer, comprising a first source, drain and gate, wherein at least one of the first source, drain, and gate has a first contact disposed thereon;
a second transistor formed on the SOI layer, comprising a second source, drain and gate wherein at least one of the second source, drain, and gate has a second contact disposed thereon;
a buried conductor disposed at a level below the first contact and second contact;
a first metal sidewall conductor connecting the first contact to the buried conductor;
a second metal sidewall conductor connecting the second contact to the buried conductor; and
an insulator layer disposed above the buried conductor.

2. The semiconductor structure of claim 1, wherein the buried conductor is comprised of a silicided region of the bulk semiconductor substrate.

3. The semiconductor structure of claim 2, wherein the silicided region comprises nickel silicide.

4. The semiconductor structure of claim 2, wherein the silicided region comprises cobalt silicide.

5. The semiconductor structure of claim 1, wherein the insulator layer disposed above the buried conductor comprises silicon oxide.

6. The semiconductor structure of claim 1, wherein the first metal sidewall conductor and the second metal sidewall conductor are comprised of tungsten.

7. The semiconductor structure of claim 1, wherein the first metal sidewall conductor and the second metal sidewall conductor are comprised of copper.

8. The semiconductor structure of claim 1, wherein the buried conductor is comprised of a deposited metal region disposed on the bulk semiconductor substrate.

9. The semiconductor structure of claim 1, wherein the buried conductor is comprised of a deposited metal region disposed within the buried oxide (BOX) layer.

10. The semiconductor structure of claim 8, wherein the deposited metal region comprises tungsten.

11. The semiconductor structure of claim 1, wherein the buried conductor is comprised of a doped region of the bulk semiconductor substrate.

12. The semiconductor structure of claim 11, wherein the buried conductor is doped with dopants selected from the group consisting of arsenic, boron, and phosphorous.

13. A semiconductor structure comprising:
a semiconductor substrate;
a first transistor formed on the semiconductor substrate, comprising a first source, drain and gate, wherein at least one of the first source, drain, and gate has a first contact disposed thereon;
a second transistor formed on the semiconductor substrate, comprising a second source, drain and gate wherein at least one of the second source, drain, and gate has a second contact disposed thereon;
a buried conductor disposed at a level below the first contact and second contact;
a first metal sidewall conductor connecting the first contact to the buried conductor;
a first spacer disposed adjacent to the first metal sidewall conductor;
a second metal sidewall conductor connecting the second contact to the buried conductor;
a second spacer disposed adjacent to the first metal sidewall conductor; and
an insulator layer disposed above and below the buried conductor.

14. The semiconductor structure of claim 13, wherein the first spacer and second spacer are comprised of silicon nitride.

15. The semiconductor structure of claim 13, wherein the buried conductor comprises a deposited metal region.

16. The semiconductor structure of claim 15, wherein the deposited metal region comprises tungsten.

17. A method of forming a semiconductor structure, comprising:
forming a first transistor formed on a semiconductor substrate, comprising a first source, drain and gate, wherein at least one of the first source, drain, and gate has a first contact disposed thereon;
forming a second transistor formed on the semiconductor substrate, comprising a second source, drain and gate wherein at least one of the second source, drain, and gate has a second contact disposed thereon;
forming a buried conductor disposed at a level below the first contact and second contact;
forming an insulator region above the buried conductor;
forming a first metal sidewall conductor connecting the first contact to the buried conductor; and
forming a second metal sidewall conductor connecting the first contact to the buried conductor.

18. The method of claim 17, wherein forming a buried conductor comprises depositing a metal.

19. The method of claim 17, wherein forming a buried conductor comprises forming a silicided region of the semiconductor substrate.

20. The method of claim 17, wherein forming a buried conductor comprises forming a doped region of the semiconductor substrate.
